(19) United States
(12) Patent Application Publication
(10) Pub. No.: US 2003/0154174 A1
(43) Pub. Date: Aug. 14, 2003

(54) Network charging

(76) Inventors: Jerome Tassel, Hadleigh (GB); Robert J Briscoe, Woodbridge (GB)

Correspondence Address: Nixon & Vanderhye, 8th Floor, 1100 North Glebe Road, Arlington, VA, 22201-4714, US

(21) Appl. No.: 10/276,863

(22) PCT Filed: Jun. 18, 2001
(86) PCT No.: PCT/GB01/02676

(30) Foreign Application Priority Data
Jun. 16, 2000 (EP) 00305130.7

(51) Int. Cl. G01R 11/56; G06F 17/00; G01R 21/133

(52) U.S. Cl. 705/412

(57) ABSTRACT

The invention provides a method of charging for a confederated network, such as the Internet, by the user terminals connected to the network. The network provide generates a tariff code, which is multicast to the user terminals. The user terminals then translate the tariff code to automatically generate a meter rule set that can be used to configure a network traffic meter.

This invention relates to the field of charging users for the use of communications networks, specifically charging users the use of internetworking communications networks.

In conventional communications networks, such as national PSTNs (public switched telephone networks), a significant proportion of the network resources are devoted to metering and billing network usage. Studies have estimated these resources as consuming as much as 6% of the operational costs of a telecommunications company. The Internet, by contrast, does not in general incorporate metering and billing mechanisms for individual users. The absence of the network infrastructure required to support metering and billing reduces the operational costs of the Internet compared to conventional telephony networks, and has facilitated the rapid expansion of the Internet. However the absence of appropriate billing mechanisms has significant disadvantages in terms of the characteristics of the traffic carried by the internet: it encourages profligate use of network resources, and diminishes the incentive for investment in network infrastructure to support new applications requiring, e.g., guaranteed quality of service (QoS).

It is known from WO99/65183 that it is possible to charge Internet users for their network use, the charge being dependent upon the number of bytes transmitted and/or received, the class of service used to transport the data, the balance between supply and demand for network resource, etc.

According to a first aspect of the invention there is provided a method of charging for use by a user terminal of a communications network, the method comprising the steps of:

(a) creating a tariff for network usage;

(b) distributing said tariff to a plurality of user terminals connected to the communications network, such that one or more of the plurality of the user terminals translates the tariff to generate a meter rule set for calculating a charge for use by the user terminal of the communications network. Preferably the user terminal configures a meter using the generated meter rule set. The tariff translation may comprise extracting a set of parameters from the tariff and may further comprise the transformation of the extracted parameters to generate the meter rule set. The tariff may be distributed as a binary file and preferably it is distributed as a Java bytecode.

According to second aspect of the invention there is provided a method of operating a network, the method comprising the steps of:

(a) creating a tariff for network usage;

(b) distributing said tariff to a plurality of user terminals connected to the communications network;

(c) additionally distributing said tariff to a network accounting server, said network accounting server translating said tariff to generate a meter rule set for calculating a charge for use by one or more user terminals of the communications network. Preferably the network accounting meter configures a meter using the generated meter rule set.

According to a third aspect of the invention there is provided a method of operating a network, the method comprising the steps of

(a) creating a tariff for network usage,

(b) distributing said tariff to a network accounting server, said network accounting server translating said tariff to generate a meter rule set for calculating a charge for use by a user terminal of the communications network, and

(c) distributing said meter rule set to a plurality of user terminals connected to the communications network. Preferably the user terminals configure a meter using the received meter rule set.

According to a fourth aspect of the invention there is provided a user terminal for connection to a communications network, the user terminal comprising; a network interface which receives, in use, tariff data from the communications network; a meter for measuring use by the user terminal of the communications network; storage means for storing data received from the communications network and network usage data generated by the meter; and a tariff translator to generate a meter rule set from said tariff data, said meter rule set, in use, being used to configure the meter.

Systems embodying the present invention will now be described in further detail, by way of example only, with reference to the accompanying drawings, in which:

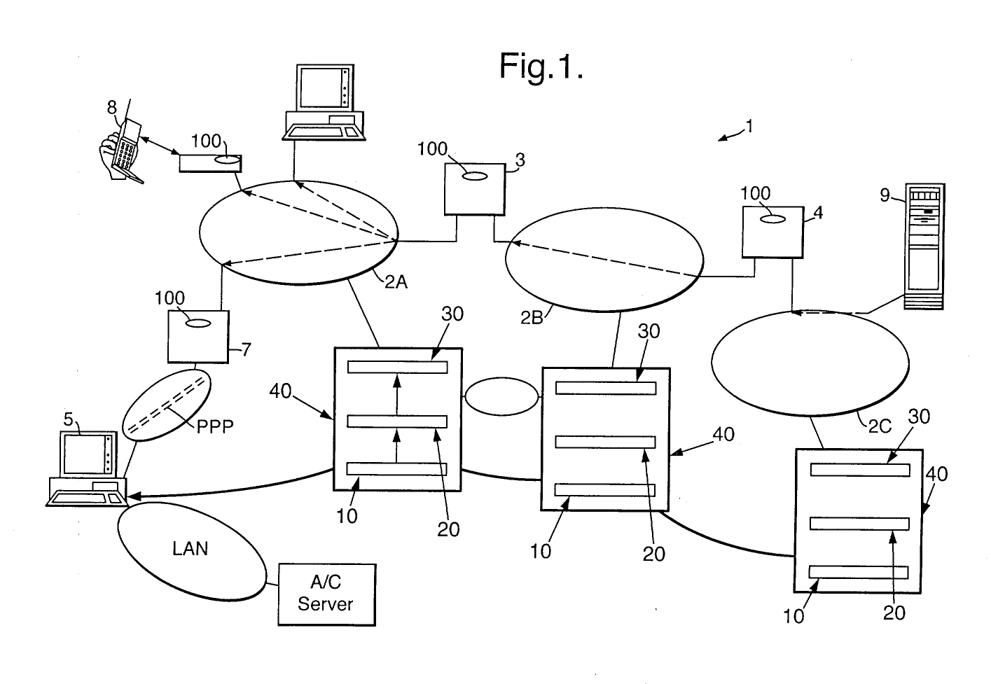

FIG. 1 is a schematic showing a network embodying the invention;

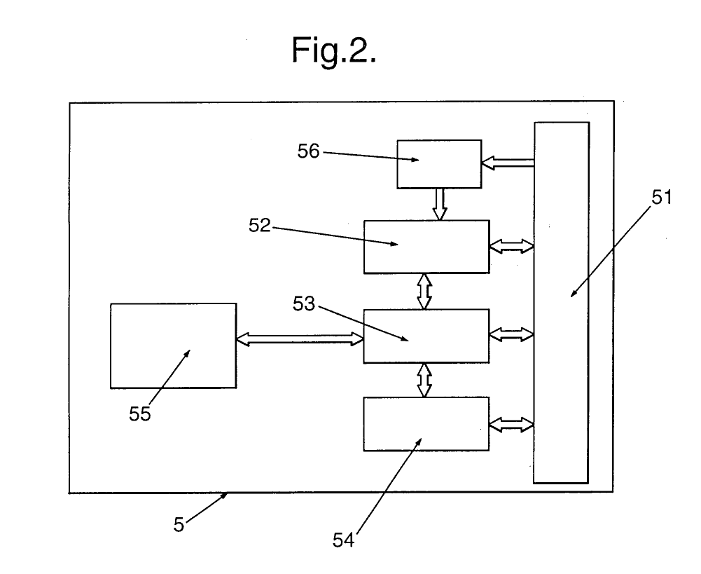

FIG. 2 is a schematic showing a user terminal for use in a network embodying the invention.

As shown in FIG. 1, a communications network 1 includes a number of network sub-domains 2A, 2B, 2C. The network sub-domains may be under the control of different operators who may not trust each other. The network subdomains are interconnected by gateway routers 3, 4. In the present example the communications network is the Internet and supports both unicast and multicast Internet Protocol (IP) and associated protocols. A customer terminal 5 is connected via a public switched telephony network (PSTN) 6 and an access router 7 to a subdomain 2A. A single blocking test is applied to traffic at this point of access. The gateway routers 3,4, and access router 7 may be commercially available devices such as CISCO series 7500 routers and CISCO series AS5800 universal access server respectively. Other customer terminals are connected to the network, including a Java-enabled mobile terminal 8 and a data server 9. The network uses network-based control of a number of tariff bands In addition to local tariff variation mechanisms as is described in WO99/65183. A network management platform 40 is connected to each subdomain. Each network management platform 40 may comprise, for example, a computing system comprising a SPARC workstation running UNIX (Solaris) together with network management applications. The network management platform 40 hosts management entities and tariff entities.

As is disclosed by Rizzo (Rizzo et al, “A Dynamic Pricing Framework to Support a Scalable, Usage-based Charging Model for Packet-switched Networks”, Proc. IWAN'99 Springer-Verlag, July 1999) tariff code is disseminated to user terminals using IP multicast channels, with tariff announcements being made such that the user terminals are aware of the latest version of the tariff and can download the latest version as necessary. The tariff is time-stamped by the network provider and signed using the private key of the network provider such that each user terminal can determine whether the latest tariff is in use. The tariff received by a user terminal is in the form of computer executable code, preferably a Java bytecode because of the advantages of cross-platform use.

Referring to FIG. 1, a tariff code is created by the marketing function 10 of the network management platform 40 in accordance with the network resource capacity, business requirements, marketing strategy, user base etc of the network provider. The creation of a network tariff and the business-specific nature of a tariff is not an aspect of the present invention and will not be discussed further. The policy server 20 is responsible for the multi-casting of the tariff code to the user terminals 5, ensuring that the tariff code is time-stamped and signed and the accuracy of any announcements regarding the latest tariff in use. Additionally the policy server 20 comprises a tariff translator, which translates the tariff code into meter rules that can be used to configure a network traffic meter (see below for a discussion of the operation of the tariff translator).

The provider accounting server 30 comprises at least one such network traffic meter. As is known from the prior art, the users are trusted to report their own network usage to the provider accounting server 30 and the associated cost. In order to encourage honest user behaviour, a number of audits of user network usage are performed and a substantial penalty cost (relative to the cost of network usage) is applied to those users who under-report the extent of their network usage (this is analogous to the business model of a “pay and display” car park). The network traffic meter of the provider can be used to measure the volume and type of network usage of a particular user when the user is being audited. The provider accounting server 30 also comprises storage means for storing the results of network usage audits and the usage data reported by each user terminal. The provider accounting server need only store sufficient aggregated traffic data to be able to demonstrate to a particular user what network resource the user has consumed, whereas the user terminal may decide to store as much (or as little) traffic data as is desired.

The tariff code is multicast to all user terminals 5 that are in communication with the network 1. Each user terminal 5 (see FIG. 2) comprises an interface 51 for communication to and from the network, a meter 52 to measure the number and type of packets received and transmitted by the terminal, storage means 53 for recording, inter alia, data created by the meter and data received from the network, a processing unit 54, a display 55 and a tariff translator 56. When tariff data is received by a user terminal the network interface 51, under the influence of the processing unit 54, passes the tariff data to the tariff translator 56. The tariff translator transforms the tariff code into a set of rules that can be used to configure the meter 52. In a preferred embodiment of the present invention, the meter rules were generated as a set of instructions for a Pattern Matching Engine (PME) (see IETF RFC2063, “Traffic Flow Measurement: Architecture”, N Brownlee, C Mills & G Ruth, January 1997) instead of statements in the high-level language SRL.

The tariff translator generates a new set of meter rules dynamically as a new tariff code is received by the user terminal (if the tariff is delivered before the time when it becomes valid then the traffic meter is not re-configured until the tariff becomes valid).

The tariff code may be represented by a plain text file, thus in this case the tariff translator must provide means for a lexical analysis (recognising the separate tokens using a dictionary of tokens) and a syntactical analysis (checking the tokens syntactically against a grammar) according to the PME language.

Alternatively, if the tariff code is represented by a binary file then the tariff translator must be able to process the tariff code by loading the tariff binary file and performing the appropriate compilation steps to create a basic PME ruleset program. It is preferred that the tariff code is multicast to the user terminals as a binary file, and in particular as a Java bytecode.

It is presumed by the tariff translator that each tariff code contains a set of parameters which can be used in order to control the meter, which will be referred to as the Measurable Parameters Set (MPS). For example, a MPS may be the packets in, packets out, packets rate, network congestion and so forth. The tariff translator, searches the tariff code, then extracts the MPS and transforms them into a meter ruleset.

As mentioned above, the network provider's policy server 20 also comprises a tariff translator. This allows the policy server to generate a meter rule set for the meter(s) in the provider accounting server. As the meter rule set is generated within the providers network domain, it is possible to multicast the meter rule set to the user terminals rather than multicasting the tariff code to the user terminals. This is an advantage for user terminals having limited processing and/or storage capabilities, such as a mobile terminal, for example a cellular telephone, as the translation process is performed by the network provider.

The network usage meters in the network provider policy server and in the user terminal may be a NeTraMet meter (see Nevil Brownlee (Univ. of Auckland), “The NeTraMet System”, Software Release Notes, December 1997) which counts packets received and transmitted according to the current meter rule set.

In a further embodiment of the present invention, the inventor has implemented a meter system using concepts derived from the ALAN (Application Level Active Networking) model described by Fry and Ghosh (“Application Level Active Networking”, Fry & Ghosh, Computer Networks, 31(7):655-667 1999). The meter system, when viewed at a high level, has two states: initialisation and operation. Once the meter has been created and initialised it switches into the operation phase, in which it provides metering and accounting functions for active applications. When the meter system requires, or is prompted for, an update then the meter system returns to the Initialisation phase.

The meter system comprises a number of proxylets (which are mobile code from third parties that can be loaded from proxylet repository servers. The advantage of loading code from common servers are that the code can be shared between multiple users and a level of trust for the code can be implied) which can be loaded and run within a generic active node (GAN) The meter system preferably comprises one or more meters, one or more dynamic accounting controllers (DACs) and a tariff translator. The meter is a specialised active node [SAN (which is a specialised case of a GAN that only accepts a specific group of proxylets in order to provide a desired functionality)] created when a GAN receives a meter code proxylet. Generally, service providers (or network providers) will control a meter using meter policies. A meter will capture packets from the network and apply a number of policies to create a number of measurements, which should be derivable from tariffs distributed by providers. A DAC is a SAN that is controlled by accounting policies in order to co-ordinate one or more meters, collecting meter data and transforming it into accounting data that can be sent to or exchanged with a service provider. The tariff translator is a proxylet that can transform a tariff source program into the meter and accounting policies used to instruct a meter and a DAC.

In the initialisation phase (which is caused, for example, by a user connecting to a network) a meter system is created and initialised using the initial configuration stored on the user terminal (this configuration may be that that was used previously). Each proxylet is numbered to aid management and the may be downloaded from a provider or from a trusted third party that has created or is sorting the tariff for a provider.

In the operation phase, the meter system will receive tariffs from providers via either multicast or unicast channels. Once a DAC receives a tariff it will load dynamically a tariff translator proxylet in order to generate the appropriate meter and accounting policies (the DAC may load a specific protocol stack in order to communicate with the meter, for example SNMP (Simple Network Management Protocol) or a proprietary protocol such as the one used with the Cisco NetFlow architecture). The DAC may periodically prompt the Meter to gather metered data or the meter may ‘push’ data to the DAC when a pre-defined event occurs (for example, the arrival of a certain number of packets, a clock timeout occurring, a specific TCP stream closing, etc.). The DAC collates all the meter data, adds user details and sends this to the provider so that a bill can be generated.

The use of such a model gives rise to a number of security requirements. The most important is that the execution of a proxylet must not compromise the integrity of the terminal on which it is executed, for example the introduction of a virus, Trojan Horse or worm. Partly this requirement is based upon the user trusting service providers or third parties who generate or supply proxylets. The ‘soundness’ of meter and accounting policies must be guaranteed so that neither a user or a provider could tamper with an aspect of the meter system. All communications between customer and provider must be secure, private and provide non-repudiation, with all meter data having sufficient integrity to reduce the chance of non-authorised alterations.

Additionally, as the metering function will be critical to the functioning of the business of providers it is likely that the metering function could be exposed to denial of service (DoS) attacks, thus the ability to mitigate against and recover from such attacks is important. In order to prevent customers from defrauding providers it will be necessary to include some form of audit of meters running on customer terminals (i.e. parallel meter systems held within provider's premises) and to analyse any logs generated by authentication and authorisation processes.

The tariffs used in the model described above must express a set of charging policies in a declarative manner. Thus, if there is a clear tariff specification then it can be translated to provide metering and accounting control. This translation may be achieved through a metric specification having the following properties:

Type: {e.g. counter, token bucket, list . . . }

Constraints: used to restrict the type domain.

Implementation scheme: algorithm describing how the metric should be implemented within the Meter system.

Associated Event: the event stating when the metric value should be accessed.

Pattern Matching Filter: used for packet and protocol-related metrics that filters isolated or group of packets to create the metric. Approaches for specifying packet filters are well known.

Such a tariff must be defined in a language that can express concepts such as

| Metric | Description |
|---|---|
| Duration (T) | Session duration: t2(stop time) − t1 (start |
| | time) |
| Volume (V) | Session volume, e.g. no. input packets, no. |
| | input bytes, no. output packets, no. output |
| | bytes. |
| Instantaneous Volume (v) | Volume within a given time interval |
| | [t + dt] |
| Loss (L) | Packet Loss indication for protocols with a |
| | given sequence number. |
| Throughput (H) | Session throughput |
| Delay (D) | Packet delay within the session |
| Peak rate (P) | Peak volume/time unit within a session |
| Average rate (A) | |
| Inter Packet Arrival Time (t) | Instantaneous time interval between packet |
| | arrivals |
| Round Trip time (RTT) | Time for a packet travelling from source |
| | to destination plus the return path |
| Maximum Packet Size (MPS) | |
| Congestion (C) | Congestion indication: ECN, ICMP source |
| | quench, packet loss |
| DSCodePoint | Diffserv classes |
| Protocol-related (e.g. RSVP | Intserv classes |
| attributes) | |
| Address attributes | IP address (src,dst), TCP ports (src,dst) |

A session is defined as a set of flows with start and stop times. The session duration is defined as t2(stop time)−t1 (start time). However, there exists a difference in session duration for billing purposes. Those times should be defined in a per session measurement. They may be the first packet for a flow within the session, or a specific control packet for a protocol (e.g. SIP control packet saying the call is already placed). Therefore, the charging application should interact in informing the events that begin and finish a session.

One important point is the mapping between flows within a session with their respective owners. The current approaches taken by the IEFT RTFM, IETF DiffServe and IntServ use the address attributes to identify a flow. Such schemes work well with measurements for hosts and static allocated IP addresses. However, another type of flow identification should be used to cope with the scenario with dynamic address allocation, for example another flow ID which can be mapped to a User ID (e.g. Username, UserID . . . ). This identification field may be a combination of Username+Microflow address attributes (source IP, destination IP, source TCP port, destination TCP port) and it may be stored in the flow label field of the IPv6 header.

Although the language should be declarative in the general form it should also allow block use of imperative commands within a policy action. In this way, the language can be used for describing both Tariff and Meter/Accounting Control. The source program in the language should also satisfy policies through type-checking [A Jeffrey et al “A survey of semantic techniques for Active networks”, IEEE Networks, Special issue on Active Networks, November 1997]. Additionally, a type in the language should be extensible in order to guarantee type specialisation, which will be useful for specialising Metric types. It should also be possible to use abstraction so that both high-level policies, such as business and charging policies, and low-level policies, such as device specific configuration, can be expressed (this requirement also relates to whether the language should be declarative).

The language used to define tariffs relies upon the following definitions:

Policy: is a rule that defines a choice in the behaviour of a system, allowing a set of rules to administer and control access to network resources.

Policy rule: we define a rule as being a combination of an event, condition and action (ECA). They are based on rule-based languages of active database systems.

Event: a happening which may be of interest of a rule. Event type can be: (a) single (originated from a single source) or (b) aggregate (originated from a combination of sources). The event source can be: (a) packet-related which comprises packet arrival events and packet header operations (bit pattern matching). (b) protocol-related which relates to isolated or group of packets arrival (e.g. protocol discovery: IGMP Join, RSVP setup msg . . . ) (c) time-related which may be absolute, relative or periodic.

Condition: examines the context in which the event took place. It may be the state of the meter system during or after the event.

Action: list of tasks to be performed if the relevant event has taken place and the condition expression is true.

A policy rule in the language used to implement his embodiment of the invention takes the following syntax:

on event

if condition

do actions

and a simple arbitrary congestion-based tariff with event-condition-action (ECA) rules could be expressed as

Tariff Name: ECN_Tariff

price_byte_unit = 0.4
ecn_marks: counter;
bytes_sent: counter in bytes;
on ecn_marks.congestion
if (price < 1000)

do {

price =ecn_price+price_byte_unit * bytes_sent;

}

The above tariff can be translated into the following Metering/Accounting policies:

Metering/Accounting Policies
on initialisation

| | |
|---|---|
| do | { |

create counter name ecn_marks bound to packet_arrival.pkt
[NETWORK_ECN_BITS] = 11
create counter name bytes_sent bound to
packet_arrival.ptk.length

}

on packet_arrival

| | |
|---|---|
| do | { |

updates bytes_sent
update ecn_marks
prepare output
}

In this example, both the ecn_marks and bytes_sent variables are counter types. The translation takes into account such a type in order to generate the output low-level policies. Thus, the type is the bind mechanism between a tariff and such metering/accounting policies. As the tariff is a high-level set of policies, it only needs to implicitly specify what to measure through the metric type. On the other hand, the metering/accounting policies describe not only what but also how to measure. Therefore, using the same policy language we should be able to specify policies in different levels (i.e. provide abstraction).

An experimental evaluation of such a meter system has been performed. An arbitrary tariff was created based on the six classes described in the quasi-model that originated from Eurescom project P906. These classes include Gold and Silver versions of Interactive Real-time services (e.g. voice over IP), Non-interactive Real-time services (e.g. video (or audio) streaming) and non-real-time services (such as email). The experiment examined a number of different scenarios (meter at customer terminal, meter at customer terminal & network congestion and meter at provider server) and the results indicate that for all of these scenarios it is possible to measure traffic-related metrics (such as data volume received and packet rates) as well as classification-related metrics for the IETF DiffServ architecture.

As will be readily understood, a user terminal could take many forms, for example a personal computer, a games console, such as a Sega Dreamcast or Sony Playstation II, a personal digital assistant, such as a Palm Pilot or Psion Revo, a set top box for cable, satellite or terrestrial broadcast systems, or a cellular telephone with suitable network capabilities, such as WAP, GPRS, EDGE, or UMTS. The translation functionality could be provided in hardware within a terminal, or as an additional piece of software. This could be provided with the terminal by the manufacturer of the terminal, or installed by a user from computer media (floppy disk, CD, DVD, etc.) or from a download from a network. The inventors have implemented a user terminal which was a personal computer using a FreeBSD PC router and a NeTraMet meter.

Although the above discussion has described the network provider policy server and the provider accounting server as being separate servers it will be understood that this is only a conceptual model and that the various processes performed by these servers could be performed by a single server or a cluster of a number of servers. Distributing the processes across as number of machines can be disadvantageous if the network is prone to congestion, whereas it might be necessary to separate the different processes in order to balance the CPU loading and input/output processing required.

1. A method of charging for use by a user terminal of a communications network, the method comprising the steps of
(a) creating a tariff for network usage
(b) distributing said tariff to a plurality of user terminals connected to the communications network, and
(c) translating the tariff to generate a meter rule set for calculating a charge for use by the user terminal of the communications network.

2. A method according to claim 1 in which the user terminal configures a meter using the generated meter rule set.

3. A method according to claim 1 or 2 in which the tariff translation comprises extracting a set of parameters from the tariff.

4. A method according to claim 3 in which the tariff translation further comprises the transformation of the extracted parameters to generate the meter rule set.

5. A method according to any preceding claim in which the tariff is distributed as a binary file.

6. A method according to claim 5 in which the tariff is distributed as a Java bytecode.

7. A method of operating a network, the method comprising the steps of
(a) creating a tariff for network usage,
(b) distributing said tariff to a plurality of user terminals connected to the communications network,
(c) additionally distributing said tariff to a network accounting server, said network accounting server translating said tariff to generate a meter rule set for calculating a charge for use by a user terminal of the communications network.

8. A method according to claim 6 in which the network accounting meter configures a meter using the generated meter rule set.

9. A method of operating a network, the method comprising the steps of
(a) creating a tariff for network usage,
(b) distributing said tariff to a network accounting server, said network accounting server translating said tariff to generate a meter rule set for calculating a charge for use by a user terminal of the communications network, and
(c) distributing said meter rule set to a plurality of user terminals connected to the communications network.

10. A method according to claim 9, in which the user terminals configure a meter using the received meter rule set.

11. A user terminal for connection to a communications network, the user terminal comprising;
a network interface which receives, in use, tariff data from the communications network;
a meter for measuring use by the user terminal of the communications network;
storage means for storing data received from the communications network and network usage data generated by the meter; and
a tariff translator to generate a meter rule set from said tariff data, said meter rule set, in use, being used to configure the meter.
